(19) United States
(12) Patent Application Publication
(10) Pub. No.: US 2006/0289092 A1
(43) Pub. Date: Dec. 28, 2006

(54) Heat dissipation device having low melting point alloy coating and a method thereof

(76) Inventor: Chun-Hou Chan, Hsi Chih City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/159,257

(22) Filed: Jun. 23, 2005

(51) Int. Cl. B22D 17/00; H05K 7/20; C21D 9/00; H01L 21/00

(52) U.S. Cl. 148/538; 148/559; 361/705; 438/122

(57) ABSTRACT

A heat dissipation device having a layer of a low melting point alloy coating and a method of fabrication are described. A low melting point alloy material is heated to above its melting point, and the melted alloy material is sprayed onto the heat sink to form a coating layer right on the heat sink for a close contact with a heat source. Manufacturing time is conserved, manufacturing operations are simpler, and thermal conduction is improved.

### BACKGROUND OF THE INVENTION

1. Field of the Invention

The present invention relates to a heat dissipation device with a low melting point alloy coating and a method of fabrication thereof, and more particularly, to a heat dissipation device coated with a layer of low melting point alloy material and a method of fabrication, which reduces fabrication time and improves thermal conductivity.

2. Description of the Related Art

With the speedy progress of computer industry, heat sources such as chips, central processing units (CPU), and the like generate too much heat as their processing speed grow faster. In order to help the heat source maintain routine operations within a permitted temperature range; a heat dissipation device generally has to have ample coverage attached to the dissipating surface of the heat source, coupled with multiple fins of Skived fin heat sink for the heat dissipation. Taiwan Pat. No. TW562395, Nov. 11, 2003 discloses such a prior-art heat dissipation device.

To ensure the heat generated by a heat source duly transferred to a heat sink, thermally conductive glue is generally applied. The heat sink dissipates the heat generated by the heat source through the aid of the thermally conductive glue.

The aforesaid prior-art heat dissipation device employs thermally conductive glue as a medium of heat transfer. Due to a relatively low thermal conductivity TC (approximately 2-3), the efficiency of thermal conduction is poor, which weakens the transfer of heat from the heat sources, such as chips, CPUs, and the like to the heat sink, and consequently reduces the efficiency of heat dissipation.

Another heat dissipation device associated with the present invention uses a low melting point alloy material adhered to a heat sink as a medium of heat transfer. The low melting point alloy material has relatively high thermal conductivity, thereby facilitating an effective transfer of heat generated by a heat source to the heat sink, and accordingly a better heat dissipation.

The aforementioned low melting point alloy material needs to be first cast into finlike structure, subsequently positioned in order on the heat sink, and then adhered to the heat sink. Therefore, the combination of a low melting point alloy material with a heat sink causes problems in taking more time to position, and is inconvenient to manufacture. Moreover, the adhesive used to attach the low melting point alloy material to the heat sink reduces the thermal conduction therebetween.

### SUMMARY OF THE INVENTION

The purpose of the present invention is to provide a heat dissipation device with a low melting point alloy coating, and a method of fabrication thereof, which method is implemented by spraying a low melting point alloy material onto a heat sink directly. The processes of positioning, adhesion, and the like are eliminated; the process according to the present invention reduces manufacturing time, and streamlines manufacturing. Additionally, the melting mount in combining the low melting point alloy material with the heat sink further augments the thermal conduction therebetween. To achieve the foregoing purpose, the present invention provides a heat dissipation device with a low melting point alloy coating. The heat dissipation device according to the present invention comprises a heat sink, and a coating, which is formed by heating a low melting point alloy material above its melting point, and spraying it onto the heat sink.

The present invention provides a method of fabricating a heat dissipation device with a low melting point alloy coating. The method comprises the following steps. A heat sink is cast. A low melting point alloy material is heated to above its melting point. The melted low melting point alloy material is sprayed onto the heat sink to form a low melting point alloy coating. The coating layer is cooled until solid to make the heat sink with the low melting point alloy coating. A further understanding on the characteristics and technological contents of the present invention is suggested by reading the following detailed description in conjunction with the appended drawings; however, the appended drawings are considered illustrative and reference, and shall not limit the present invention.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a flow chart illustrating the method of fabricating the heat sink with a low melting point alloy coating according to the present invention; and

FIG. 2 is an elevation view illustrating the heat sink with the layer of low melting point alloy coating according to the present invention.

### DETAILED DESCRIPTION OF PREFERRED EMBODIMENTS

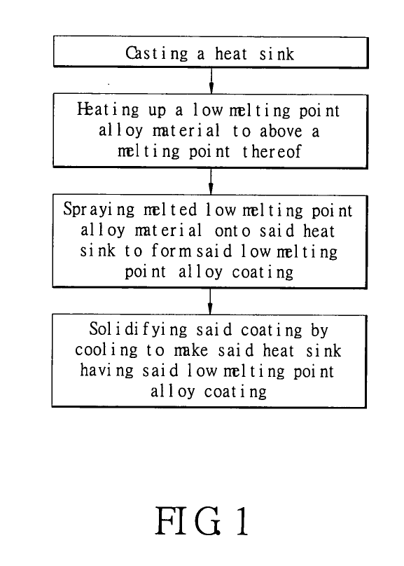

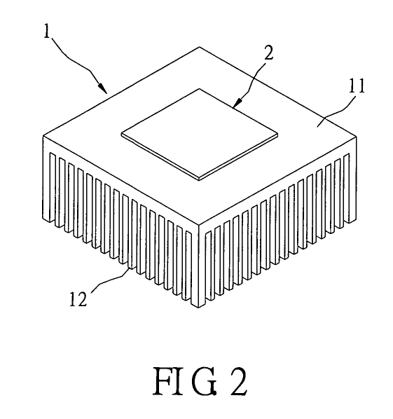

With reference to FIG. 1, the present invention provides a method of fabricating a heat dissipation device with a low melting point alloy coating, comprising the steps of: (refer also to FIG. 2)

(a) A heat sink 1 is cast. The heat sink 1 is made of metal with good thermal conduction such as copper or aluminum. The shape and structure of the heat sink 1 are not restricted, and the heat sink 1 can be categorized as any type. In this particular embodiment of the present invention, the heat sink 1 comprises a base 11 and a plurality of sink fins 12 extruding from the base 11. Additionally, a process liquid such as alcohol is used to cleanse the surface of the base 11 of the heat sink 1, or the surface is ground by a fine abrasive paper, to enhance adhesive strength of the low melting point alloy material.

(b) The low melting point alloy material is melted to above its melting point. The low melting point alloy material can be an alloy with a relatively low melting point, such as lead, tin, lead-tin, and the like.

(c) The melted low melting point alloy material is sprayed onto the base 11 of the heat sink 1 to form a low melting point alloy coating 2, and the coating 2 adheres to the surface of the base 11 of the heat sink 1. The coverage and thickness of the coating 2 vary, subject to the actual demand, where the thickness is regulated by the number of spraying process processes.

(D) The coating 2 is cooled to room temperature, and thereby solidified. The heat sink 1 with low melting point alloy coating 2 is thus made.

The foregoing procedures can be implemented in ordinary places, but a better outcome can be expected in a clean room.

With reference to FIG. 2, the present invention provides a heat dissipation device with a low melting point alloy coating, comprising a heat sink 1 and a coating 2. The heat sink 1 comprises a base 11 and a plurality of sink fins 12 extruding from the base 11, and the coating 2 formed by heating the low melting point alloy material to above its melting point and by spraying it onto the base 11 of the heat sink 1 to form the heat sink 1 having the low melting point alloy coating 2. The present invention employs a coating 2 made of a low melting point alloy material to attach fast on a heat sink 1, and, by means of a contact between the coating 2 and a heat source, allows the low melting point alloy material to act as a medium of thermal conduction. Due to a relatively high thermal conductivity of the low melting point alloy material, bubbles (hollows) can be avoided and an effective transfer of heat generated by the heat source to the heat sink 1 enabled for better heat dissipation.

Since the low melting point alloy material is directly sprayed onto the heat sink 1, there is no need for positioning, adhering and the like; therefore, the low melting point alloy material (the coating 2) reduces the amount of time needed for fabrication, and streamlines the manufacturing process. Additionally, the melting mount, in combining a low melting point alloy material with a heat sink into one object, can further augment the thermal conduction in between.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are embraced within the scope of the invention as defined in the appended claims.

What is claimed is:

1. A heat dissipation device with a low melting point alloy coating, comprising:
a heat sink; and
a coating, having a low melting point alloy material heated up to above a melting point thereof and sprayed onto said heat sink.

2. The heat dissipation device with a low melting point alloy coating as claimed in claim 1, wherein said heat sink comprises a base and a plurality of sink fins extruding from said base, said coating being formed on said base.

3. The heat dissipation device with a low melting point alloy coating as claimed in claim 1, wherein said low melting point alloy material is lead, tin, or a lead-tin alloy.

4. A method of fabricating a heat dissipation device with a low melting point alloy coating, comprising the steps of:
casting a heat sink;
heating up a low melting point alloy material to above a melting point thereof;
spraying melted low melting point alloy material onto said heat sink to form said low melting point alloy coating; and
solidifying said coating by cooling to make said heat sink having said low melting point alloy coating.

5. The method of fabricating a heat dissipation device with a low melting point alloy coating as claimed in claim 4, wherein said low melting point alloy material is lead, tin, or lead-tin alloy.

6. A method of fabricating a heat dissipation device with a low melting point alloy coating as claimed in claim 4, wherein said melted low melting point alloy material is sprayed onto said heat sink by a sprayer.

7. The method of fabricating a heat dissipation device with a low melting point alloy coating as claimed in claim 4, wherein said coating solidifies by cooling at room temperature.
